(19) United States
(12) Patent Application Publication
(10) Pub. No.: US 2009/0327837 A1
(43) Pub. Date: Dec. 31, 2009

(54) NAND error management

(76) Inventors: Robert Royer, Portland, OR (US); Sanjeev N. Trika, Hillsboro, OR (US); Rick Coulson, Portland, OR (US); Robert W. Faber, Hillsboro, OR (US)

Correspondence Address: Caven & Aghevli LLC;c/o CPA Global, P.O. BOX 52050, MINNEAPOLIS, MN, 55402, US

(21) Appl. No.: 12/215,915

(22) Filed: Jun. 30, 2008

(51) Int. Cl. G11C 29/04; G06F 11/22

(52) U.S. Cl. 714/763; 714/E11.145

(57) ABSTRACT

Techniques to manage various errors in memory such as, e.g., NAND memory in electronic devices are disclosed. In some embodiments, erase, read, and program error handling errors are managed.

### RELATED APPLICATIONS

This application is related to the following applications: U.S. patent application Ser. No. 10/739,608, to Royer, et al., filed Dec. 8, 2003, entitled VIRTUAL CACHE FOR DISK CACHE INSERTION AND EVICTION POLICIES AND RECOVERY FROM DEVICE ERRORS; U.S. patent application Ser. No. 11/254,508, to Trika, et al., filed Oct. 20, 2005, entitled METHOD TO ENABLE FAST DISK CACHING AND EFFICIENT OPERATIONS ON SOLID STATE DISKS, the disclosures of which are incorporated herein by reference in their entirety.

### BACKGROUND

Power Computer systems store data to different types of storage media and devices. Such storage media and devices may be considered nonvolatile, and persistently store data when power to a computer system is turned off. An example of a nonvolatile storage device is a hard disk of a computer system. Storage devices may also include NAND flash memory and solid state disks (SSD). Storage media may include actual discs or platters that are accessed through the storage device. An operating system (OS) executing on a processor may request or perform actions, such as read and write, to particular locations on a storage medium.

Data written to and read from locations in these particular storage devices may be structured in blocks. Bits representing digital information (i.e., 1 or 0) may be grouped as data. In the storage devices, the bits may be stored in cells. Cells may be organized into pages. Therefore, a page is representative of the data. The size of a page typically is about 2,048 bytes for NAND flash memories; however, this is not typical for hard disk drives (HDD). In certain instances, the page may be a different size.

In some non-volatile memories, such as NAND-Flash, pages may be placed into erase blocks. An erase block typically includes about 64 pages, although in certain instances, an erase block may include a different number of pages. In such memories, it is typically required that all pages in a given erase block be erased together rather than individually.

Furthermore, in non-volatile memories such as NAND flash memory, it is typically required that pages are erased before they are written. Erased pages are also sometimes referred to as “blank” or “blank pages”. Thus, only blank pages can be written to. To write to the same page twice, the page is erased after the first write and before the second write. An exception to this rule is that bits in a written page may be toggled from “1” to “0” without an intermediate erase.

When an action such as a write is performed on a page of a storage device or storage medium, the entire erase block containing that page is first read into a temporary location, then the erase block is erased, and all the data is rewritten to the blank pages in the erase block, including the data from the temporary buffer for all but the requested page write, and the new data for the requested page write. Thus, a page write typically requires read, erase, and write operations on the entire erase block containing the page, which is relatively quite slow. The temporary locations may be in volatile memory of the computer system.

The number of erase cycles performed on erase blocks of memory like NAND flash memory may be limited. Typically, it is recommended that such erase actions are performed for no more than 100,000 cycles for each erase block.

Thus, in addition to degradation issues seen at erase blocks from multiple erase cycles, performance issues also exist when performing actions affecting entire erase blocks. Moving pages to and from erase blocks and temporary locations involves significant input/output (IO) traffic in a computer system and uses considerable processor (i.e., controller) resources.

### BRIEF DESCRIPTION OF THE DRAWINGS

The detailed description is described with reference to the accompanying figures, in which:

FIG. 1 is a schematic illustration of a computer system that may be adapted to implement NAND error management, according to some embodiments.

FIG. 2A is a block diagram of page metadata information included in nonvolatile memory of such a disk cache or solid state disk, according to some embodiments.

FIG. 2B is a block diagram of page metadata information included in volatile memory for controlling such a disk cache or solid state disk, according to some embodiments.

FIG. 3 is a flow diagram illustrating a process to manage a NAND read error, according to some embodiments.

FIG. 4 is a flow diagram illustrating a process to manage a NAND read error, according to some embodiments.

FIG. 5 is a flow diagram illustrating a process to manage a NAND read error, according to some embodiments.

FIG. 6 is a flow diagram illustrating a process to manage write access errors, according to some embodiments.

### DETAILED DESCRIPTION

Described herein are exemplary systems and methods for implementing NAND error management which, in some embodiments, may be implemented in an electronic device such as, e.g., a computer system. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

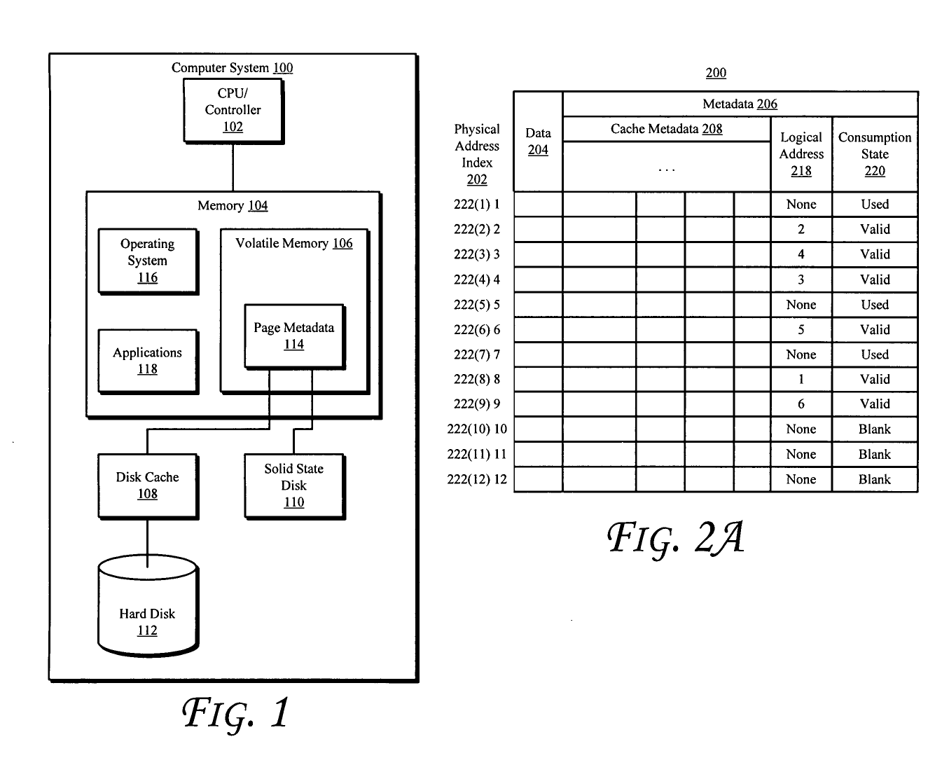

FIG. 1 illustrates a computer system 100 that provides a disk cache and/or a solid state disk (SSD). Computer system 100 includes one of various devices and systems such as personal computers (PC), laptop computers, and server computers. Computer system 100 may be particularly configured to perform fast or efficient caching (i.e., more efficient operations on storage media) to a storage device or hard disk drive implementing a disk cache. Alternatively, computer system 100 may be configured to include a solid-state drive (SSD) implemented as specified in this application. The particular computer system 100 that is illustrated shows both a disk cache and an SSD. It is contemplated that particular implementations of computer system 100 may have only a disk cache or an SSD, and in certain cases (as illustrated here) both a disk cache and an SSD are implemented. Examples of storage devices include NAND flash memory, NOR flash memory, polymer memory, or any other non-volatile memory organized in erase blocks containing memory pages.

Computer system 100 includes a central processing unit (CPU) or controller 102. In certain embodiments, controller 102 is a dual or multiple processor that includes multiple controllers. Controller 102 may be used for various processes in computer system 100, and particularly may include a memory and disk controller.

A memory 104 is included in computer system 100. The memory 104 is controlled by the controller 102. The memory 104 may include one or more memories such as random access memory (RAM). Memory 104 may include volatile and nonvolatile memory wherein data is lost in volatile memory and data is not lost in nonvolatile memory when computer system 100 is turned off. In this example, memory 104 particularly includes a volatile memory 106. Volatile memory 106 may be dynamic random access memory (DRAM).

Alternatively, the volatile memory 106 may reside in a disk cache 108, or a SSD 110, rather than separate from the disk cache 108 and/or SSD 110. Furthermore, a controller (not shown) may reside inside the disk cache 108 or the SSD 110, or a hard disk drive (HDD) 112. The resident controller particularly controls the volatile and non-volatile memory accesses. In addition, the disk cache 108 may be on a separate bus rather than connected as a filter as shown in the FIG. 1. In particular implementations, disk cache 108 resides in HDD 112.

In this example, volatile memory 106 stores page metadata 114. The page metadata 114 includes consumption state information of the pages (i.e., pages identified by specific physical addresses). The consumption state information includes three states: used, valid, and blank. As further described below, the use of consumption state information allows actions on individual pages to be performed, thereby avoiding the need to erase entire blocks. This enables fast disk caching and solid-state-disk operation by performing actions on individual pages instead of entire erase blocks.

Memory 104 may store an operating system 116 executable by controller 102. Application programs or applications 118 may be stored in memory 104. Applications 118 are run by operating system 116. Operating system 116 is particularly used to perform read and write operations to volatile memory 106 and a storage device such as hard disk 112 and/or SSD 110. Such operations may be performed as a result from requests from applications 118.

Disk cache 108 is included in computer system 100. In implementations where a memory device such as an SSD 110 is used in place of HDD 112, similar logic or processes as performed by disk cache 118 is performed by SSD 110. Data sent to memory 104 (i.e., operating system 116 or applications 118) from HDD 112, goes through disk cache 108 and/or SSD 110.

Disk cache 108 is particularly used for actions performed on HDD 112. For example, a read request is performed by operating system 116. If the data is found in the disk cache 108, the data is sent from disk cache 108 to the operating system 116. If the data is not found in disk cache 108, the data is read from the HDD 112.

If a write action is performed by operating system 116, the data is sent to disk cache 108 and/or to the HDD 112 depending on disk caching logic. During times when the operating system 116 is not active, the data may be sent from the disk cache 108 to the HDD 112.

Information in page metadata 114 includes information as to state of individual pages, and a logical to physical address mapping table, that allows faster disk caching and SSD 110 operations (i.e., more efficient operations) by permitting operations to single pages rather than multiple actions on entire blocks (i.e., erase blocks).

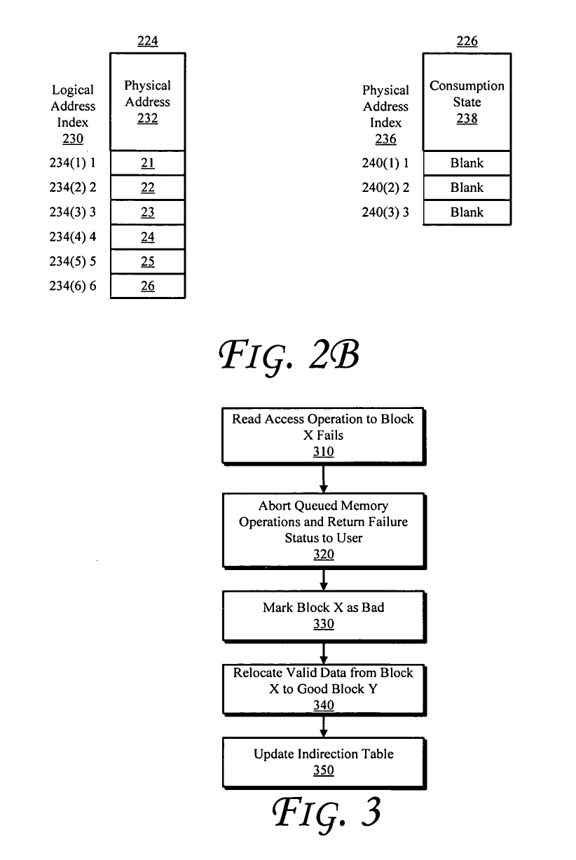

FIG. 2A illustrates layout of data and page metadata in nonvolatile memory such as disk cache 108 or solid state disk (SSD) 110. In particular, table 200 supports what is described as dynamic addressing of nonvolatile memory on a disk cache 108 or a SSD 110. The dynamic addressing continually changes the mapping between the logical addresses and physical addresses to ensure that each logical write operation causes data to be stored in a previously erased location (i.e., at a different physical address) of the nonvolatile memory. Thus, with dynamic addressing, each logical write operation produces a single operation on a page. This is to be compared to typical addressing that use three accesses to the containing erase block of a nonvolatile memory (one to read the data at the erase block containing the specified address, one to erase/invalidate an old erase block, and the third to write the updated data at the erase block).

Table 200 includes a physical address index 202 which indexes a physical address of a physical location in a storage medium or storage device, such as included in disk cache 108 or SSD 110. Table 200 particularly does not include a physical addresses, but accesses physical addresses through physical address index 202. An index points to a physical address, where a physical address defines a particular page in a particular erase block where data is stored.

Table 200 includes a field for data 204 which represents actual data. Table 200 further includes metadata as represented by metadata field 206. Metadata field may include a field cache metadata 208 that describes metadata used by disk cache 108; however, this field may be not required for SSD 110 operation. Included in cache metadata 208 are sub-fields directed to typical prior art cache metadata or application specific metadata, as represented in the following exemplary fields: tag=disk LBA (logical block address) field 212, valid bit field 214, dirty bit field 216, etc. It is well known in the art to include such information or application specific metadata.

A logical address field 218 and a consumption state field 220 are provided in order to allow fast disk caching or efficient SSD operations on storage media. The logical address field 218 represents an address to which the operating system 110, disk cache 118, or logic in an SSD 116 may go for data. In particular, algorithms in disk cache 118 or in SSD 116 refer to logical addresses as defined by the field for logical address 218, in performing the actions to and from the disk cache 108 or SSD 110. The consumption state field 220 represents one of three consumption states of a page. A first consumption state is “blank”, which indicates that data can be written to the page. A second consumption state is “valid”, which indicates that data is present in the page and may be read. A third consumption state is “used”, which indicates that data is present in the page, but it is no longer valid or may not be read. Pages identified as “used” are pages which can be erased. By providing consumption state information for pages, actions (e.g., write or erase) can be performed on pages without having to perform an action on an erase block.

In this example, table 200 includes twelve data entries 222(1) to 222(12) that occupy physical pages 1 to 12, and are indexed by physical address index 202. In specific, data entry 222(1) is indexed by physical address index 1; data entry 222(2) is indexed by physical address index 2; data entry 222(3) is indexed by physical address index 3; and so on.

The pages as defined by their physical address indices may be grouped in erase blocks. For example, pages as defined by indices 1, 2, 3, and 4 are grouped in an erase block 1; pages as defined by indices 5, 6, 7, and 8 are grouped in an erase block 2; and pages as defined by indices addresses 9, 10, 11, and 12 are grouped in an erase block 3. The number of pages and their grouping are for illustration, and it is expected that typical erase blocks will include more than four pages, and that the disk cache 108 and the SSD 110 will include more than three erase blocks

Disk cache 108 or SSD 110 may have a limitation as to a maximum number of logical pages they may address. For example, in this illustration, the maximum may be 6 pages. Therefore, six pages in entries 222 can have a consumption state of “valid”. In this example, such entries are entry 222(2), entry 222(3), entry 222(4), entry 222(6), entry 222(8) and entry 222(9). The other entries of entries 222 are either “used” or “blank”.

FIG. 2B illustrates page metadata information in volatile memory such as volatile memory 106. In particular, a logical address to physical address (L2P) table 224, and a blank pool table 226 may be stored in volatile memory 106.

L2P table 224 includes a logical address index field 230 and a physical address field 232. Logical address index field 230 particularly provides an index to a logical address; however, L2P table 224 does not include a logical address. Entries 234 include indexes to logical addresses and corresponding physical addresses.

Blank pool table 226 includes a physical address index field 236 and a consumption state field 238. It is contemplated that for typical implementations, blank pool 236 does not include consumption state field 238, since only physical addresses having a consumption state of “blank” need be identified in blank pool table 226. In other words, the blank pool table 226 is simply a list of physical addresses for which the consumption state is blank in table 220. Each entry of entries 240 include physical addresses (i.e., indices to physical addresses) having a consumption state of “blank”. By identifying available or blank pages, the disk cache 108 or SSD 110 logic can write to particular blank pages. In certain implementations, table 200 may also be included in volatile memory without the data 204 field. In volatile memory, table 200 allows relatively fast and more efficient identification of erase blocks that are mostly empty and required table lookup logic to update the page metadata on relocations.

Since information in table 200 is stored in nonvolatile memory (i.e., disk cache 108 and/or SSD 110), in the event that data is corrupted, erased, or made unavailable (i.e., not kept after power down) in volatile memory 106, data in tables 224 and 226 may be created or recreated using data from table 200. This enables, for example, power-failure recovery for both the disk-caching and the solid-state disk applications despite constantly changing logical-to-physical address mapping, and maintenance of the L2P table 224 in volatile memory.

Storage is one of the biggest performance bottlenecks in computer systems. In some embodiments, a computer system 100 may implement write-back disk-caching on non-volatile memory can significantly alleviate the performance bottleneck, while at the same time offering power-savings benefits, critical especially for mobile platforms. Solid State Disks offer similar benefits. The related applications incorporated by reference above implement algorithms for disk cache and SSD applications on non-volatile (NV) memories such as NAND flash that have high write latencies and data organized in pages that are be erased in an erase block (EB) before they can be written again. These algorithms have the following characteristics: a) An indirection table L2P is used to map logical addresses to physical page address, b) Writes to a logical address is written to a blank physical page, and the L2P is updated to point to this page, c) At idle times, valid pages in an erase block are relocated to another erase block before erasing the first block, and d)For each write to a logical address, a sequence number is saved in page metadata to enable identification of the current (most recent) write for the logical address. This facilitates proper power-fail recovery.

These methods, however, assume that the underlying solid-state non-volatile memory does not have any errors during read, write and erase operations. In practice, errors occur during read, write, and erase operations periodically and need to be managed without destroying data integrity whenever possible in order to maintain reliable operation. Thus, described herein are embodiments of techniques to manage read, program error, and read errors in a computer system such as the computer system 100. Without loss of generality, and for illustrative purposes only, the underlying non-volatile memory is described in the context of NAND, although the techniques are applicable to other types of memory. Thus, described herein are novel methods for NAND error handling for reliable disk-cache and SSD operation.

Exemplary techniques are described with reference to FIGS. 3-6. The methods that are described are illustrated as a collection of blocks in a logical flow graph, which represent a sequence of operations that can be implemented in hardware, software, firmware, or a combination thereof. In the context of software, the blocks represent computer instructions that, when executed by one or more processors, perform the recited operations. The processes are described with reference to computer system 100 and tables 200, 224, and 226 described above. Although described as flow diagrams, it is contemplated that certain processes may take place concurrently or in a different order.

The three primary types of errors are erase errors, program (write) errors, and read failures, and handling each of these is explained below. A common theme in the error handling algorithms is that an error causes the underlying block to be marked as a “bad” block. If possible, any current (valid) data in the block is moved out to another erase block. This relocation is followed by a remap of any previously queued memory access operations to the failing block. It is possible for unexpected loss of power to occur while the system is in the process of relocating data from a failed erase block. The system may defer updating the NV bad block list until all current (valid) data has been relocated. If power fails before the NV (Non Volatile) bad block list is updated, the system will rediscover the bad block during the next power cycle.

FIG. 3 is a flow diagram illustrating a process to manage read access errors, according to some embodiments. At operation 310 a memory read access error occurs in a given memory block referred to as block X. At operation 320 all queued memory operations, including the access with error, are aborted and a failure status is returned to the user. At operation 330 the block X is marked as bad. At operation 340 all valid data from block X is relocated to a good block. At operation 350 the indirection table is updated.

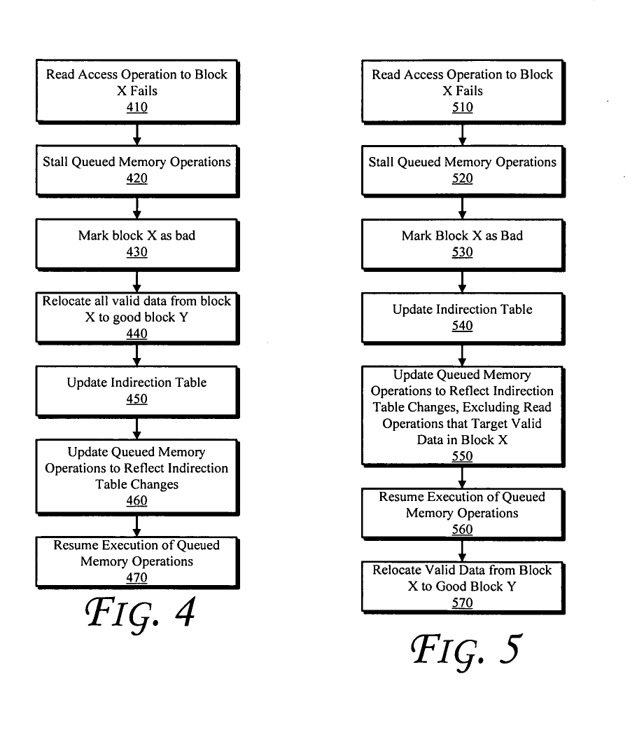

FIG. 4 is a flow diagram illustrating a process to manage memory read access errors that preserves queued memory accesses behind the memory read access error, according to some embodiments. Queued memory accesses could be, for example, NAND memory erase, program, or read operations.

At operation 410 a memory read access error occurs in a given memory block referred to as block X. At operation 420 all queued memory operations, including the access with error, are aborted and a failure status is returned to the user. At operation 430 the block X is marked as bad. At operation 440 all valid data from block X is relocated to a good block. At operation 450 the indirection table is updated. At operation 460 the queued memory operations are updated to reflect the changes made to the indirection table in operation 450. At operation 470 execution of queued memory operations is resumed.

In certain circumstances it is possible for the system to discover uncorrectable read errors in data that has not been requested by the user. In such cases the system may internally flag the error, but should not notify the user until the user requests the data. In the event that the user overwrites the data at the flagged (failed) logical address before reading, the flagged error is overwritten, and the user never experiences the read error.

FIG. 5 is a flow diagram illustrating a process to manage a NAND read error, according to some embodiments. At operation 510 a memory read access error occurs in a given memory block referred to as block X. At operation 520 all queued memory operations, including the access with error, are aborted and a failure status is returned to the user. At operation 530 the block X is marked as bad. At operation 540 the indirection table is updated. At operation 550 the queued memory operations are updated to reflect the changes made to the indirection table in operation 450, with the exception of read operations that target valid data in block X. At operation 560 execution of queued memory operations is resumed. At operation 570 all valid data from block X is relocated to a good block.

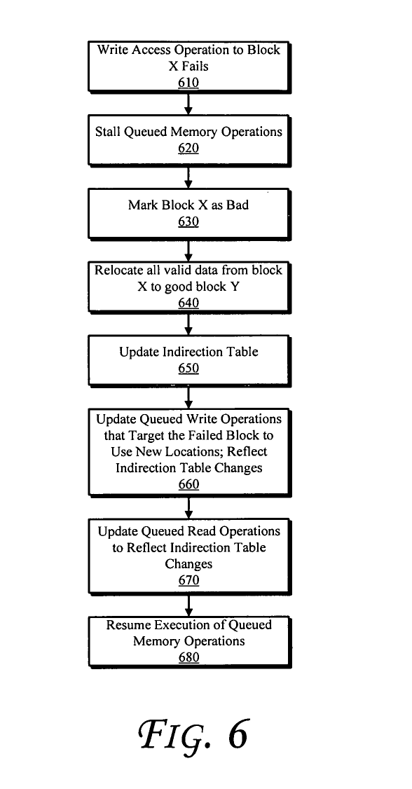

FIG. 6 is a flow diagram illustrating a process to manage write access errors, according to some embodiments. At operation 610 a memory write access error occurs in block X. At operation 620 all queued memory operations, including the access with error, are aborted and failure status is returned to the user. At operation 630 the block X is marked as bad. At operation 640 all valid data from block X is relocated to a good block. At operation 650 the indirection table is updated. At operation 660 queued write operations that target locations in the failed block are reprocessed to target locations in a good block. At operation 670 queued read accesses up updated to reflect the indirection changes. At operation 680 normal command execution is resumed.

“Logic instructions” as referred to herein relates to expressions which may be understood by one or more machines for performing one or more logical operations. For example, logic instructions may comprise instructions which are interpretable by a processor compiler for executing one or more operations on one or more data objects. However, this is merely an example of machine-readable instructions and embodiments are not limited in this respect.

The terms “computer readable medium” as referred to herein relates to media capable of maintaining expressions which are perceivable by one or more machines. For example, a computer readable medium may comprise one or more storage devices for storing computer readable instructions or data. Such storage devices may comprise storage media such as, for example, optical, magnetic or semiconductor storage media. However, this is merely an example of a computer readable medium and embodiments are not limited in this respect.

The term “logic” as referred to herein relates to structure for performing one or more logical operations. For example, logic may comprise circuitry which provides one or more output signals based upon one or more input signals. Such circuitry may comprise a finite state machine which receives a digital input and provides a digital output, or circuitry which provides one or more analog output signals in response to one or more analog input signals. Such circuitry may be provided in an application specific integrated circuit (ASIC) or field programmable gate array (FPGA). Also, logic may comprise machine-readable instructions stored in a memory in combination with processing circuitry to execute such machine-readable instructions. However, these are merely examples of structures which may provide logic and embodiments are not limited in this respect.

Some of the methods described herein may be embodied as logic instructions on a computer-readable medium. When executed on a processor, the logic instructions cause a processor to be programmed as a special-purpose machine that implements the described methods. The processor, when configured by the logic instructions to execute the methods described herein, constitutes structure for performing the described methods. Alternatively, the methods described herein may be reduced to logic on, e.g., a field programmable gate array (FPGA), an application specific integrated circuit (ASIC) or the like.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A method to manage read failures on an indirected, non-volatile (NV) block memory in an electronic device, comprising:
detecting an operational failure in a NV memory block;
relocating valid user data from the NV memory block associated with the operational failure to a good block;
marking the NV memory block associated with the operational failure as bad; and
updating the indirection table.

2. The method of claim 1, further comprising:
aborting queued operations to the NV memory block associated with the operational failure; and
delivering a failure status to the user for each queued operation.

3. The method of claim 1, further comprising:
stalling queued memory operations to NV memory in the electronic device;
updating queued operations to reflect the updated indirection table; and
resuming execution of queued operations to NV memory in the electronic device.

4. The method of claim 3, further comprising:
skipping updates for at least one queued read operation that targets valid data in the NV memory block associated with the operational failure.

5. The method of claim 3 further comprising:
marking as bad data associated with the NV memory block associated with the operational failure;
delivering a failure status to the user for a read failure;
delivering a failure status to the user on subsequent read operations of the marked data; and
unmarking the data as failed when the data is re-written by the user.

6. The method of claim 5, further comprising:
withholding delivery of a failure status to the user when the failing read access was not initiated by the user.

7. The method of claim 1 wherein the non-volatile memory comprises NAND memory.

8. The method of claim 7 wherein the indirection system is page-level indirection.

9. The method of claim 1, further comprising moving invalid user data.

10. The method of claim 1, wherein the read error represents a failure to correct NV data with an error correction code.

11. The method of claim 1 where the read error represents an error correction code for NV data operations which succeed with a number of corrections that exceeds a specified threshold.

12. A method to manage write failures on an indirected, non-volatile (NV) block memory in an electronic device, comprising:
detecting an operational failure in a NV memory block;
relocating valid user data from the NV memory block associated with the operational failure to a good block;
marking as bad the NV memory block associated with the operational failure; and
updating the indirection table.

13. The method of claim 12, further comprising:
stalling queued NV memory operations;
updating queued write operations that target the failed block to new use new locations and update indirection table;
updating queued read operations to reflect the updated indirection table; and resuming execution of queued operations.

14. The method of claim 12, wherein the non-volatile memory comprises NAND memory.

15. The method of claim 12, wherein the indirection system comprises page-level indirection.

16. The method of claim 12, further comprising moving invalid user data.

17. A system, comprising:
a controller;
a non-volatile storage device; and
logic to:
manage read failures on an indirected, non-volatile (NV) block memory in an electronic device, comprising:
detect an operational failure in a NV memory block;
relocate valid user data from the NV memory block associated with the operational failure to a good block;
mark the NV memory block associated with the operational failure as bad; and
update the indirection table.

18. The system of claim 17, further comprising logic to:
abort queued operations to the NV memory block associated with the operational failure; and
deliver failure status to the user for each queued operation.

19. The system of claim 17, further comprising logic to:
stall queued memory operations to NV memory in the electronic device;
update queued operations to reflect the updated indirection table; and
resume execution of queued operations to NV memory in the electronic device.

20. The system of claim 17, further comprising logic to:
skip updates for at least one queued read operation that targets valid data in the NV memory block associated with the operational failure.
